(19) United States
(12) Patent Application Publication
(10) Pub. No.: US 2024/0271451 A1
(43) Pub. Date: Aug. 15, 2024

(54) A Data Centre System and Method of Construction

(71) Applicant: Andrew Tuohey, New Farm, Queensland (AU)

(72) Inventor: Andrew Tuohey, New Farm, Queensland (AU)

(21) Appl. No.: 18/566,819

(22) PCT Filed: Jun. 1, 2022
(86) PCT No.: PCT/AU2022/050534

§ 371 Date: Dec. 4, 2023

(30) Foreign Application Priority Data
Jun. 4, 2021 (AU) 2021901677

(51) Int. Cl. E04H 5/02; B66C 17/06; E04H 5/00; H05K 7/14

(52) U.S. Cl. CPC E04H 5/02; B66C 17/06; E04H 2005/005; H05K 7/1497

(57) ABSTRACT

The invention provides a data centre including a building structure comprising an internal space for containing equipment modules and a lifting device adapted to lift, lower and move horizontally equipment modules within the internal space of the building structure. In embodiments, the invention provides a power section of a data centre wherein the equipment modules are comprised of power equipment modules. The invention enables data centre equipment modules including the standby generators and power supply and distribution systems to be prefabricated off-site and supplied in a skid mounted form so that they can be transported to site, unloaded and quickly installed into the building structure.

### TECHNICAL FIELD

The present invention relates to the field of data centres and to structures containing equipment with high power demands.

### BACKGROUND

Data centres are buildings dedicated to housing computer systems and associated components, such as telecommunications and data storage systems. In addition to the computing and data storage operations of the data centre, other essential components of a data centre include power generation and distribution systems as well as environmental controls (i.e. temperature and humidity).

Large data centres are comprised of multi-storey buildings with footprints in the order of thousands of square metres. Such data centres may be designed so that the computing and data storage components are provided on different levels to power plant and equipment.

A large data centre in the 30 MW or 60 MW or 120 MW power consumption category may comprise dozens of large, diesel standby generators and dozens of modules comprising power distribution equipment. The computing equipment must be provided with a constant supply of power so the diesel generation capacity must be sufficient to replace the utility power supply in the event of a black-out.

The power distribution equipment includes transformers for receiving high voltage utility power and converting this to a lower voltage. An uninterrupted power supply (UPS) receives, conditions and distributes power to computers, servers, data communication systems and other equipment. The UPS is constantly monitoring and conditioning power supplied to the sensitive data equipment by eliminating surges, noise and spikes.

An automatic transfer switch (ATS) configured to sense the loss of power and start the generators and transfer generator power to the UPS. The UPS will bridge power during brief outages until the generator can come online to support the power requirements. The UPS systems are supported by batteries that supply power during outages or interruptions.

Other systems include environmental control systems. These control heating, cooling and humidity. This equipment ensures that humidity and air temperature within the data centre is maintained at optimum levels. The performance and longevity of computer and other electrical equipment in the data centre is affected by temperature and humidity.

Accordingly, the major electrical equipment for a data center's “Power Section” typically comprises a combination of Medium Voltage (MV) or Low Voltage (LV) Switchboards, Motor Control Centers (MCC's), Uninterrupted Power Systems (UPS) and Batteries, Ring Main Units (RMU) Transformers, Controls, Bus Duct and various pieces of equipment and Standby Generators.

A data center's major electrical equipment is generally installed by one of three methods. In a first method, the electrical equipment is shipped loosely, without any substantial prefabrication or assembly and is installed manually, component by component, on site within the data center. In a second method, the major electrical equipment is prefabricated, off-site into the form of transportable prefabricated electrical “skids” in sets, and accordance with the data center's design. In a third method; the major electrical equipment is integrated into prefabricated switchrooms off-site that are transported to the site. This last method requires a relatively large site to accommodate multiple switchrooms. Also, once the switchrooms are installed they may still require a considerable amount of manual work, on-site to complete. For example, incoming and/or outgoing cabling needs to be run, terminated and tested. The individual switchrooms also need to be individually commissioned and commissioned in their interconnection with other equipment.

Accordingly, data centres are very capital intensive and it is critical to their economic viability that they can be constructed as quickly and efficiently as possible. To this end, it is desirable to maximise the extent of prefabrication and preassembly of components off-site so as to minimise the amount of on-site assembly and testing. It is also desirable to simplify and speed up the time required to install prefabricated and preassembled components into a data centre to minimise the length of time it takes to construct and commission a data centre. It is also desirable to configure a data centre in a manner so that individual modules and equipment can be readily maintainable and be replaced if necessary.

Any discussion of background art throughout the specification should in no way be considered as an admission that any of the documents or other material referred to was published, known or forms part of the common general knowledge.

### SUMMARY OF THE INVENTION

Accordingly, in one aspect, the invention provides a data centre including:

a building structure comprising an internal space for containing equipment modules;

a lifting device adapted to lift, lower and move horizontally equipment modules within the internal space of the building structure.

Embodiments of the invention are advantageous as they enable data centre equipment modules including the standby generators and power supply and distribution systems to be prefabricated off-site and supplied in a skid mounted form so that they can be transported to site, unloaded and quickly installed into the data centre.

In embodiments, the invention provides a power section of a data centre wherein the equipment modules are comprised of power equipment modules. In embodiments, the invention provides a data section of a data centre wherein the equipment modules are data equipment modules.

Preferably, the lifting device includes a hoist for lifting and lowering an equipment module.

Preferably the hoist is horizontally translatable to desired locations within the building structure. In embodiments, the hoist is horizontally translatable to any location within the building structure at which the equipment module is to be lowered to its final position. Embodiments of the invention are advantageous as they require a single step for manoeuvring the equipment module from the location at which it is received on-site to its final installed location within the building structure and without requiring an additional manoeuvring step, or sequence of steps, such as translating the equipment module while being supported on a base of the building structure.

Preferably the lifting device includes a pair of spaced apart and longitudinally extending rails and a transverse beam extending between the rails, the beam being translatable in a longitudinal direction along the rail and the hoist being translatable transversely along the beam.

Preferably the equipment modules are configured to be stacked one upon another.

Preferably, the building structure includes a base supporting the stacked equipment modules.

Preferably, the equipment modules include power equipment modules. The power equipment modules comprise electrical equipment modules that may include any one or more of medium voltage (MV) or low voltage (LV) switchboards, motor control centers (MCC's), uninterrupted power systems (UPS) and batteries, ring main units (RMU), transformers, controls and bus duct equipment.

Preferably, the power equipment modules can comprise a standby generator module. In embodiments, the standby generator module includes a diesel power generator, such as a 1 MW diesel power generator, including its fuel supply and ancillary components.

Preferably the equipment modules include structural support members that are adapted to support the weight of one or more equipment modules stacked thereon.

Preferably, a row of stacked electrical equipment modules are provided along one side of the building structure.

Preferably a row of stacked standby generator modules are provided along an opposite side of the building structure. The positioning of electrical equipment modules and standby generator modules on opposite sides of the building structure is adopted as a means of segregation.

Preferably electrical transformers are located between the stacks of electrical equipment modules.

Preferably, the building structure includes a second base and a second lifting device above or below the first base and the first lifting device. In other embodiments, the building structure can include three or more bases and three or more lifting devices.

Preferably, a second row of stacks of the equipment modules and are provided on the second base. In an embodiment, a second row of stacks of the electrical equipment modules and standby generator modules are provided on the second base.

Preferably, the upper one of the first and the second base includes an opening to allow the lifting device to lift and lower an equipment module therethrough.

Preferably, the building structure includes a loading area adapted for receiving an equipment module on a transport vehicle.

In embodiments, floor members are adapted to engage the equipment modules.

Preferably, the floor members are adapted for connection between successive horizontally adjacent equipment modules.

Preferably, the floor members are adapted to provide landings, walkways and function as interconnecting structures and to support electrical or mechanical services.

Preferably the floor members are configured to key together with the equipment modules whereby the equipment modules, at least in part, support the floor members above the base.

In another aspect, the invention provides a method of assembling a data centre, the method including:
providing a supporting base;
lifting a first equipment module above the supporting base, horizontally translating the first equipment module to a desired location and lowering the equipment module onto the supporting base;
lifting a second equipment module above the supporting base, horizontally translating and lowering the second equipment module onto the first equipment module.

Preferably, the method includes positioning the equipment module beneath a lifting device comprising a hoist, lowering and coupling the hoist to the equipment module lifting the hoist and thereby lifting the equipment module coupled thereto.

Preferably, the method includes levelling the second module on top of the first equipment module before fixing the equipment modules together.

Preferably including lifting, horizontally translating and lowering a floor member into a position for connection with at least one equipment module.

Preferably the floor member and the equipment module are configured to key together with the equipment modules whereby the equipment modules, at least in part, support the floor members above the base.

In another aspect, the invention provides a prefabricated equipment module for a data centre adapted to be stacked one upon another, the equipment module including:
a frame comprising a base for supporting equipment and one or more support members upstanding from the base;
a coupling adapted to couple the bottom of the frame of one of the equipment modules to the top of the frame of an equipment module below.

Preferably, the coupling includes a mating element provided on the bottom of the frame of the upper equipment module and a complementary mating element provided on the top of the frame of the equipment module below, wherein the mating elements are configured to mate together to secure the equipment modules together.

Preferably, the mating element provided on the bottom of the frame is configured to mate with a vehicle or trailer to thereby secure the equipment module to the vehicle or trailer during transport.

Preferably, the frame is configured to key together with a floor member positioned immediately adjacent to the equipment module to, at least in part, support the floor member.

Preferably, the equipment module can comprise an electrical equipment module comprising any one or more of medium voltage (MV) or low voltage (LV) switchboards, motor control centers (MCC's), uninterrupted power systems (UPS) and batteries, ring main units (RMU), transformers and bus duct equipment.

Preferably, the equipment module can comprise a standby generator module comprising a diesel power generator.

### BRIEF DESCRIPTION OF THE FIGURES

The present invention will now be described in more detail with reference to preferred embodiments illustrated in the accompanying figures, wherein:

FIG. 1 illustrates a flowchart of a method of installing electrical equipment modules in a power section of a data centre in accordance with an embodiment of the invention;

FIG. 2 illustrates a flowchart of a method of installing landings, walkways and interconnecting structures and electrical or mechanical services risers in a data centre in accordance with an embodiment of the invention;

FIG. 3 illustrates a perspective view of a power section of a data centre comprising a row of stacked electrical equipment modules along one side of the structure and a row of stacked standby generators along an opposite side of the structure and a lifting device in accordance with an embodiment of the invention;

FIG. 4 illustrates a front view of the power section of FIG. 3;

FIG. 5 illustrates a side view of the power section of FIG. 3;

FIG. 6 illustrates a top view of the power section of FIG. 3;

FIG. 7 illustrates a magnified view of a portion of the side view of FIG. 5 illustrating further detail in relation to the form of the electrical equipment modules and floor members;

FIG. 8 illustrates a perspective view of a power section of a data centre in accordance with another embodiment comprising rows of stacked electrical equipment modules along both sides of the structure and a lifting device;

FIG. 9 illustrates a front view of the power section of FIG. 8;

FIG. 10 illustrates a perspective view of a power section of a data centre in accordance with another embodiment with two levels each comprising a row of stacked electrical equipment modules along one side of the structure and a row of stacked standby generators along an opposite side of the structure and a lifting device;

FIG. 11 illustrates a front view of the power section of FIG. 10;

FIG. 12 illustrates a side view of the power section of FIG. 10;

FIG. 13 illustrates a perspective view of a power section of a data centre in accordance with another embodiment with two levels each comprising rows of stacked electrical equipment modules along both sides of the structure and a lifting device;

FIG. 14 illustrates a front view of the of FIG. 13;

FIG. 15 illustrates a perspective view of a power section of a data centre in accordance with another embodiment with two levels each comprising a row of stacked electrical equipment modules and a transformer module adjacent to each electrical equipment module and a lifting device;

FIG. 16 illustrates a perspective view of a power section of a data centre in accordance with another embodiment with two levels each comprising a row of stacked electrical equipment modules and a transformer module adjacent to each electrical equipment module and a lifting device.

FIG. 17 illustrates a top view of the power section of FIG. 16;

FIG. 18 illustrates a front view of a power section of a data centre in accordance with another embodiment comprising a row of stacked electrical equipment modules along one side of the structure and a row of stacked standby generator modules along an opposite side of the structure, a dividing wall therebetween and a lifting device.

FIG. 19 illustrates a top view of the power section of FIG. 18;

FIG. 20 illustrates a top view of the power section of FIGS. 8 and 9.

The invention will now be described in further detail with reference to the embodiments illustrated in the Figures.

### DETAILED DESCRIPTION

Data centres often are comprised of three components, IT infrastructure, power infrastructure and climate control or cooling infrastructure. The IT infrastructure comprises computer and telecommunications equipment and data storage equipment. The IT infrastructure of a large data centre may contain many thousands of servers which must be fed a constant supply of power. This IT equipment is contained within an enclosed building structure which may have a footprint in the order of thousands of square metres. The building, or the section of the building containing the IT infrastructure may be referred to as the IT section of the data centre. The IT infrastructure is sensitive equipment and the humidity and temperature of the air, or climate, within the IT section must be carefully controlled.

The IT section and the climate control infrastructure of a data centre requires a substantial amount of power. Also, the power must be supplied constantly and without interruption. A large data centre can have a constant power consumption requirement of around 30 MW or more. This is a substantial amount of power and for this reason such data centres are located where utility power infrastructure exists that would service such a high power demand. Furthermore, such power is often delivered at relatively high voltages, in the kV range.

Accordingly, large data centres will have power transformers to convert high voltage power received from the utility power source to lower voltages used by other equipment within the data centre including IT infrastructure, power infrastructure and climate control infrastructure. Such centres may also have distribution power transformers for distributing power internally to various equipment within the data centre.

From time to time, black-outs can occur and for this reason, data centres must have standby power generation that can be activated to power the equipment within the data centre. Accordingly, large data centres in the 30 MW category will comprise dozens of large diesel power generators as standby generators. A 1 MW diesel power generator including its fuel supply and ancillary components will weigh many tonnes and can have dimensions in the order of 7×3×3 metres. A 30 MW data centre may have approximately 12 or more such standby generators. It is to be appreciated that a data centre may require more than 30 MW in which case the data centre may have more than 12 such standby generators. The number of standby generators will be a function of the power requirements of the data centre.

### Power Section—Structure and Lifting Device

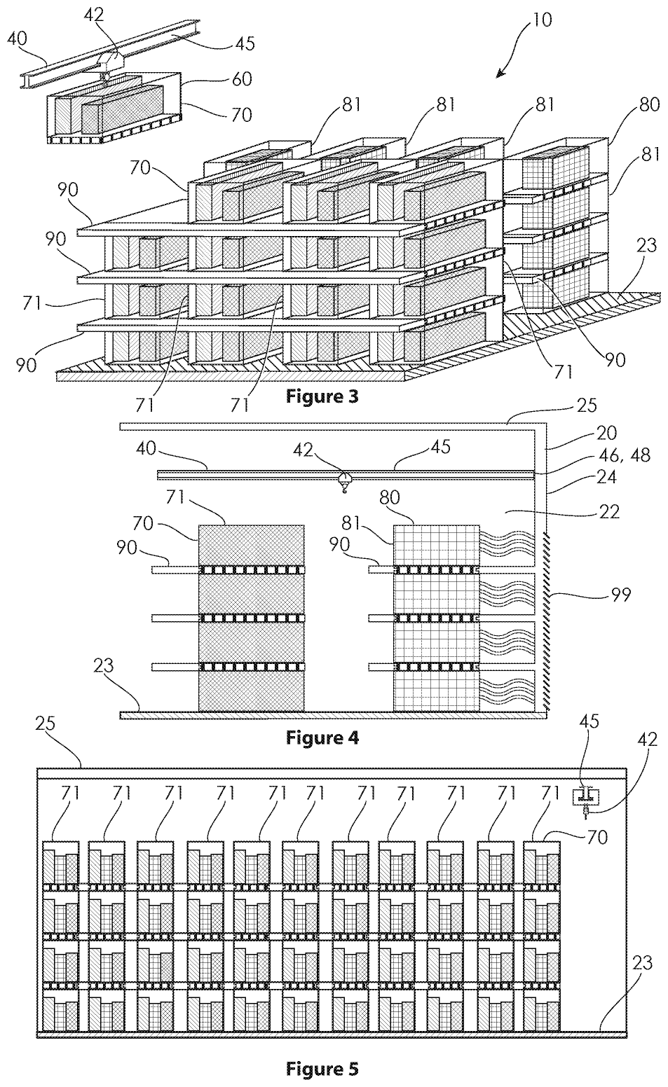

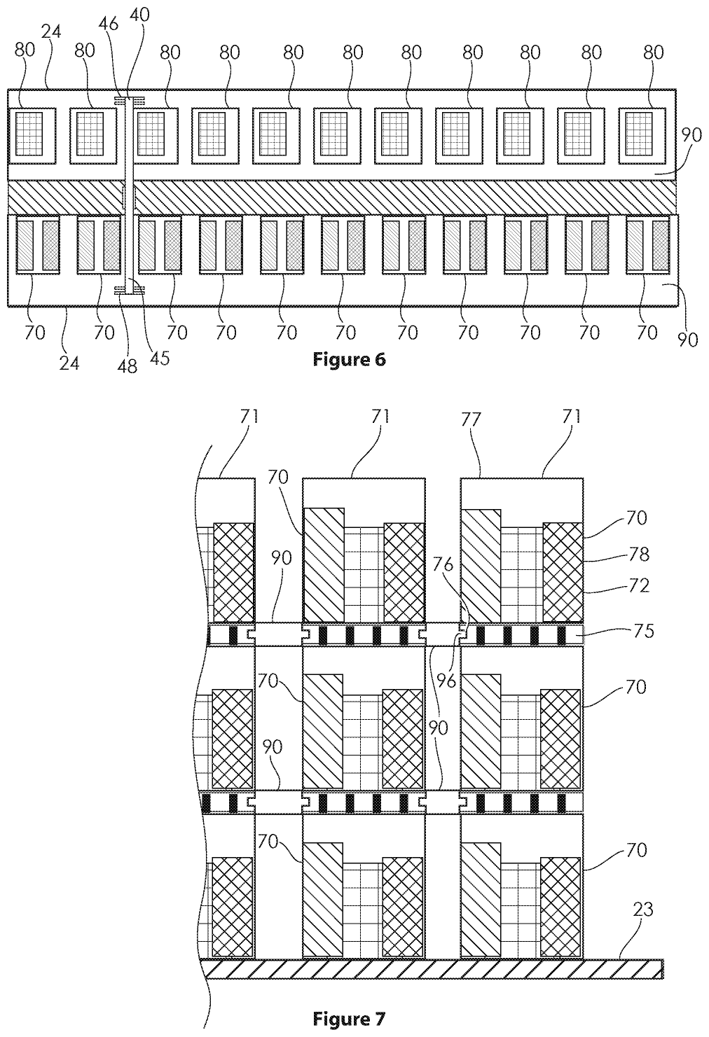

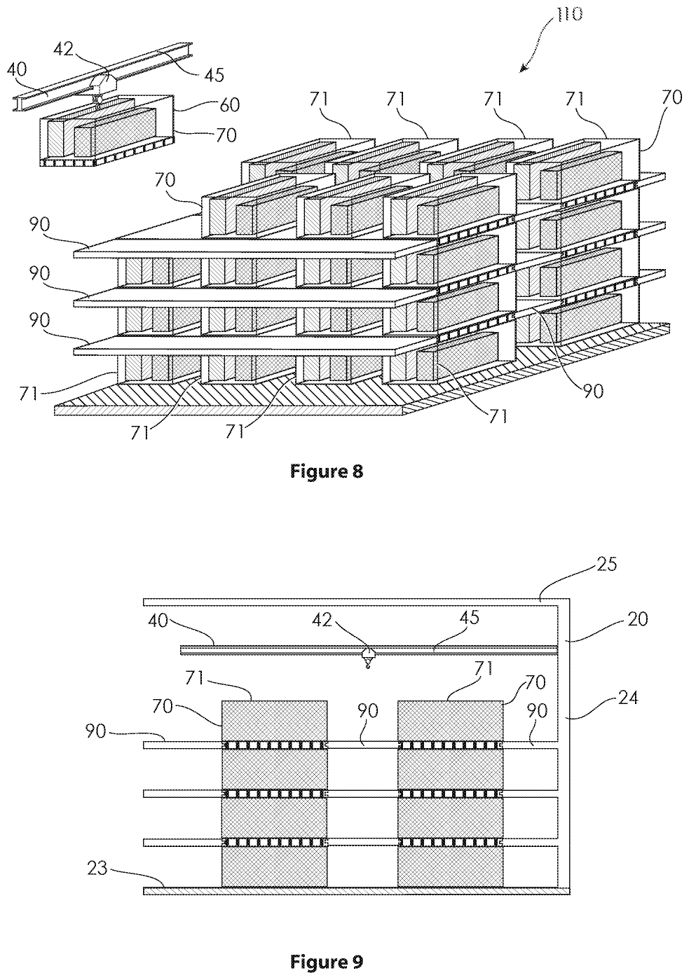

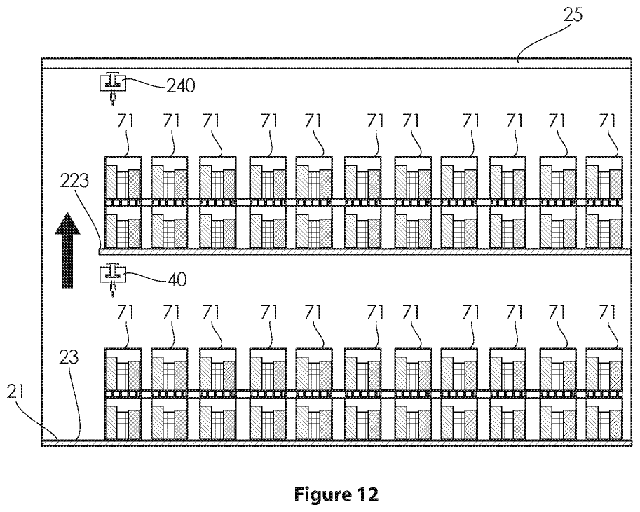

Referring to FIGS. 3 to 19, there are shown various power sections 10, 110, 210, 310, 410, 510, 610 of a data centre in accordance with embodiments of the invention. For convenience, the following will comprise a description of the first embodiment of the power section 10 of FIGS. 3 to 7 followed by a description of the distinguishing features of the other embodiments of FIGS. 8 to 19.

Although the figures illustrate various embodiments of a power section of a data centre and methods of assembling thereof comprising power equipment modules, it is to be appreciated that the invention also has application in relation to a data section of a data centre. In particular, embodiments of the invention envisage a data section of a data section comprising data equipment modules.

The major electrical equipment for the data center contained within the power section 10 typically comprises a combination of Medium Voltage (MV) or Low Voltage (LV) Switchboards, Motor Control Centers (MCC's), Uninterrupted Power Systems (UPS) and Batteries, Ring Main Units (RMU) Transformers, Controls, Bus Duct and various pieces of equipment and Standby Generators.

Referring to FIG. 3, the power section 10 includes a building structure 20 comprising an internal space 22 for containing power equipment modules 60. The building structure 20 includes a base floor 23 and as illustrated in FIG. 4 includes a structural wall 24 upstanding therefrom. The structural wall 24 is adapted to support wall cladding and other internal structural feature of the building structure as will become apparent in the foregoing description. Atop the structural wall 24 is a roof structure 25 for enclosing the building structure 20.

The power section 10 further includes a lifting device 40 that is adapted to lift, lower and move horizontally the power equipment modules 60 within the internal space 22 of the building structure 20. Embodiments of the invention are advantageous in that the lifting device 40 facilitates moving power equipment modules 60 from one location to another without need for an external crane or the removal of wall or roof members of the building structure. Accordingly, once the building structure 20 is constructed and the lifting device 40 is installed, the power equipment modules 60 can be installed quickly and efficiently and without exposure to wind or rain that can hamper ordinary external crane lifting activities.

The lifting device 40 includes a hoist 42 that is adapted for lifting and lowering the power equipment module 60. The hoist 42 is mounted on a transverse beam 45 which in turn extends between and is mounted on a pair of longitudinally extending rails 46, 48. The rails 46, 48 are supported in an elevated position, ideally immediately below the roof structure 25 and running alongside opposite walls 24 of the building structure 20. The transverse beam 45 is mounted to the rails 46, 48 in a manner such that the beam 45 can traverse longitudinally back and forth along the length of the rails 46, 48. Likewise, the hoist 42 is mounted to the beam 45 so that the hoist 42 can traverse back and forth along the beam 45 transversely between the rails 46, 48. Thus, the hoist 42 can be manoeuvred horizontally to any location along X and Y axes within the internal space 22 of the building structure 20. A common name for the lifting device 40 is an overhead crane or bridge crane.

### Power Equipment Modules

The power equipment modules 60 are comprised of two different types. One type of power equipment module 60 is an electrical equipment module 70 and the other type is a standby generator module 80.

The electrical equipment module 70 comprises a frame 72 including a base 75 and one or more uprights 77 upstanding from the base 75. The uprights 77 can take any suitable form. However, in the presently illustrated embodiments, the uprights 77 are comprised of upright structural wall members 78 that are fixed to the peripheral edges of the base. Preferably, although not necessarily, a roof member 79 is supported on and is fixed to the upper edges of the structural wall members 78.

The electrical equipment module 70 comprises a combination of Medium Voltage (MV) or Low Voltage (LV) Switchboards, Motor Control Centers (MCC's), Uninterrupted Power Systems (UPS) and Batteries, Ring Main Units (RMU), Transformers and Controls.

The aforementioned electrical equipment is provided on the base 75. The wall members 78 and the roof member 79 are provided to contain the equipment in a substantially sealed modular structure. The electrical equipment module 70 can be prefabricated off-site and transported on a vehicle or trailer to the site of the power section 10, 110, 210, 310, 410, 510, 610 for installation. The wall members 78 and roof structure 79 render the module 70 weatherproof.

The wall members 78 upstanding from the base are configured to form structural members for supporting the weight of one or more like electrical equipment modules 70 stacked one upon another. Also, the frame 72, including the base 75, wall members 78 and the roof structure 79 are capable of supporting the weight of the frame 72 itself and the electrical equipment contained therein when being lifted by the lifting device 40.

The wall members 78 or the roof structure 79, or both, may be provided with a means for connection with the hoist 42 of the lifting device 40. In embodiments, the frame 72 comprises a corner casting configured to cooperate with a twistlock commonly in use in relation to shipping containers. In embodiments, the hoist 42 is provided with a spreader, similar to those used for lifting shipping containers, or like means for connection with the corner castings for lifting and lowering the power equipment module 60. The spreader has a locking mechanism at each corner that attaches to the corner castings of the frame 72 of the electrical equipment module 70.

The frame 72 may include corner castings at the top and bottom. In addition to facilitating lifting of the electrical equipment module 60 the corner castings may, in conjunction with twistlock devices, facilitate securing together the four corners of the frames 72 of electrical equipment modules 70 stacked one upon another. The base floor 23 of the building structure 20 may also be provided with twistlock devices fixed onto the which the lowermost electrical equipment module 70 is placed.

The standby generator module 80 is identical in many respects to the electrical equipment module 70. The standby generator module 80 also comprises a frame 82 comprised of a base 85 and one or more uprights 87 upstanding from the base 85. The uprights 87 can take any suitable form. However, for present purposes, the uprights 87 are comprised of structural wall members 88 that are fixed to the peripheral edges of the base 85. Preferably, a roof member 89 is supported on and is fixed to the upper edges of the structural wall members 88. The standby generator module 80 can comprise a large diesel power generator, such as a 1 MW diesel power generator including its fuel supply and ancillary components. In another form, the standby generator module 80 may comprise an alternative form of combustion engine coupled to a generator. For example, a gas turbine engine.

The wall members 88 upstanding from the base 85 are configured to form structural members for supporting the weight of one or more like standby generator modules 80 stacked one upon another. The frame 82 also may include corner castings at the top and bottom for operation with twistlock devices as described above to facilitate lifting the standby generator module 80 and securing together the four corners of the frames 82 of standby generator modules 80 stacked one upon another. The base floor 23 of the building structure 20 may also be provided with fixed twistlock devices onto which the lowermost standby generator module 80 is placed.

### Data Equipment Modules

In embodiments of the invention comprising a data section of a data section comprising data equipment modules, the data equipment module (not shown) is similar in many respects to the electrical equipment module 70. The data equipment module also comprises a frame comprised of a base and one or more uprights upstanding from the base functioning which may include structural wall members that are fixed to the peripheral edges of the base. A roof member is supported on and is fixed to the upper edges of the structural wall members. The data equipment modules are adapted to contain computers, servers, data communication systems and other equipment. Embodiments of the invention call for the data centre equipment modules including the standby generators and power supply and distribution systems to be prefabricated off-site and supplied in a skid mounted form so that they can be transported to site, unloaded and installed into the data centre.

### Rows of Stacked Power Equipment Modules

As described above, the electrical equipment modules 70 and the standby generator modules 80 are configured to be stacked one upon another to form electrical equipment module stacks 71 and standby generator module stacks 81. As illustrated in FIG. 3, each stack 71, 81 may include up to four of the modules 70, 80 stacked one upon another. However, more or fewer than four of the modules 70, 80 may be stacked as appropriate and as the structural strength of the electrical equipment modules 70 and the standby generator modules 80 will allow.

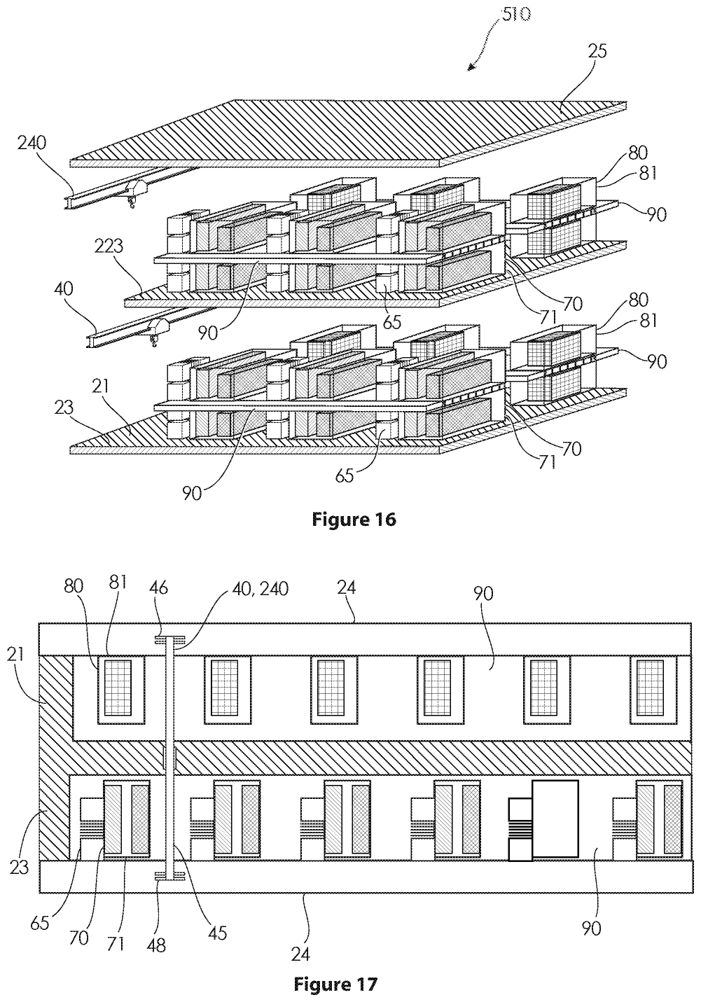

As illustrated in the embodiment of FIGS. 3 to 7, a row of stacked electrical equipment modules 70 are provided along one side of the building structure 20 and a row of stacked standby generator modules 80 are provided along an opposite side of the building structure 20. FIG. 16 illustrates an embodiment in which other equipment such as transformer modules 65 may be positioned adjacent to each of the electrical equipment modules 70.

In embodiments of the invention comprising a data section of a data centre comprising data equipment modules, the data equipment modules are also adapted to be stacked one upon another.

In other embodiments, of the invention the electrical equipment modules 70 and the standby generator modules 80 are configured to be arranged on one level. That is, not stacked one upon another but rather in a side-by-side manner. Such a data centre may have a relatively large footprint given that the power modules, and optionally also the data equipment modules, may be located on a single level and not stacked one upon another.

### Floor Members

As illustrated in FIGS. 3 to 7, floor members 90 are provided that are adapted to be connected between successive horizontally adjacent power equipment modules 60. As will be appreciated, the floor members 90 are coupled to the modules 60 so are to be removable and not to be permanently fixed. The floor members 90 function as landings and walkways. The floor members 90 can also function as interconnecting structures.

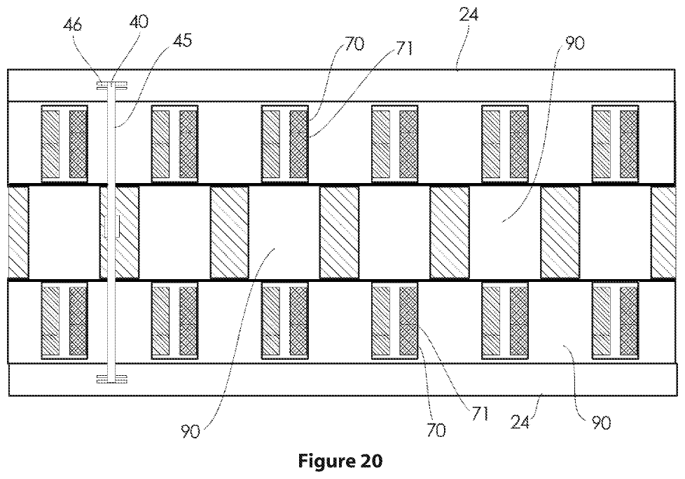

In the embodiments illustrated in the Figures, the floor members 90 are structural panels and are preferably formed out of steel, such as sheet steel or steel mesh or may be formed as precast concrete panels. The floor members 90 may be formed out of lightweight (e.g. aerated) concrete which may be reinforced. In some embodiments, such as the embodiment of FIGS. 8, 9 and 20, the floor members 90 are provided for connecting horizontally adjacent power equipment modules 60 and creating access by providing thoroughfares between the modules 60.

As best illustrated in FIG. 7, a keyway 76, in the form of a longitudinal slot, is provided in the sides of the base 75 of the frame 72 of the electrical equipment module 60. A key 96, in the form of a longitudinal protrusion, is formed on the sides of the floor members 90. The keyway 76 in the sides of the base 75 of the frame 72 receives the key 96 on the side of the floor members 90. Thus, floor members 90 are supported, at least in part, by the electrical equipment modules 60. The floor members 90 may also be supported by the walls 24 of the building structure 20, such as is illustrated in FIG. 4, or by other support structures or columns (not shown). As illustrated in FIGS. 3 to 7, some of the floor members 90 are connected between, and supported by, horizontally adjacent and spaced apart power equipment modules 60.

The floor members 90 are adapted to be lifted and positioned within the building 20 by the lifting device 40. In embodiments, the floor members 90 are formed with anchors, such as mushroom or plate anchors. The hoist 42 can be configured to employ lifting clutches for engaging the anchors and thereby allowing the hoist 42 to lift the floor members 90 and move them into position.

FIGS. 8, 9 and 20 illustrate an embodiment of the power section 110 in which the floor members 90 may also be provided between opposite electrical equipment modules 70 and standby generator modules 80 on opposite sides of the building structure 20 to provide a walkway therebetween. The floor members 90 enable technicians to walk directly across from an electrical equipment module 70 to a standby generator module 80. Specifically, the floor members 90 may be formed out of a prefabricated steel structure that can be installed via lifting device 40. It is to be appreciated that in further embodiments of the arrangements illustrated in FIGS. 3 to 19, there may be provided such floor members 90 extending between power equipment modules 60 located on opposite sides of the building structure 20 to provide a walkway therebetween.

### Base Floors and Lifting Devices

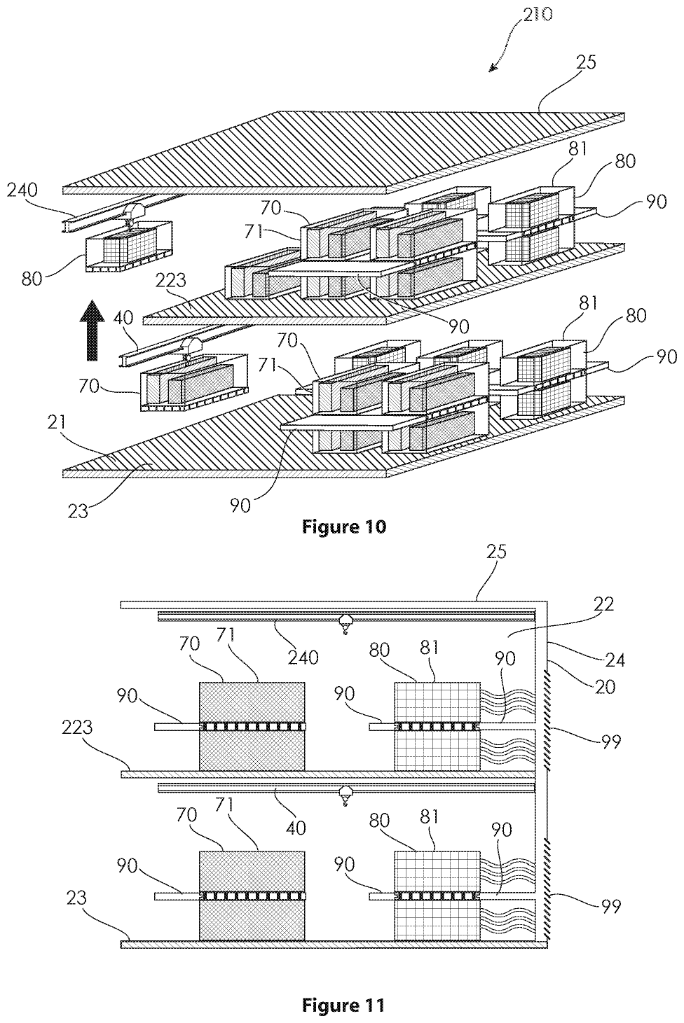

Referring to FIG. 10, there is shown an embodiment of the building structure 210 including a first base floor 23 and a second base floor 223. The building structure 210 also includes a first lifting device 40 and a second lifting device 240. The first lifting device 40 is adapted for lifting and positioning power equipment modules 60 that are prefabricated off-site including electrical equipment modules 70, standby generator modules 80 and floor members 90 into position on the first base floor 23. The second lifting device 240 is adapted for lifting and positioning prefabricated electrical equipment modules 70, standby generator modules 80 and floor members 90 into position on the second base floor 223.

The upper one of the first and the second base floors 223 has an opening 221 for the upper one of the first and the second lifting devices 240 servicing the upper floor 223 to access a loading area 21 on the lower one of the first and the second base floors 23. A skid mounted and prefabricated electrical equipment module 70 or a skid mounted and prefabricated standby generator module 80 on a transport vehicle can be manoeuvred onto the loading area 21 and lifted by either one of the first and second lifting devices 40, 240. The loading area 21 is contained within the building structure 20 such that loading, unloading and installation of the modules 70, 80, floor members 90 and any other equipment can occur in a weather shielded environment.

In embodiments of the invention comprising a data section of a data centre comprising data equipment modules, the prefabricated and skid mounted data equipment modules are also adapted to be transported and lifted in the same manner as described above for the power equipment modules 60.

### Ventilation/Cooling

Referring to the embodiments of FIGS. 3 to 7 and 10 to 11, the row of stacked standby generator modules 80 are provided along the same side of the building structure 20. As illustrated in FIGS. 4 and 11, ventilation equipment can be located between the standby generator modules and the adjacent wall members 88. The adjacent wall members 88 may comprise louvres 99 to facilitate ventilation. The standby generator modules 80 may be spaced apart from the louvres 99 or located immediately adjacent to the louvres 99.

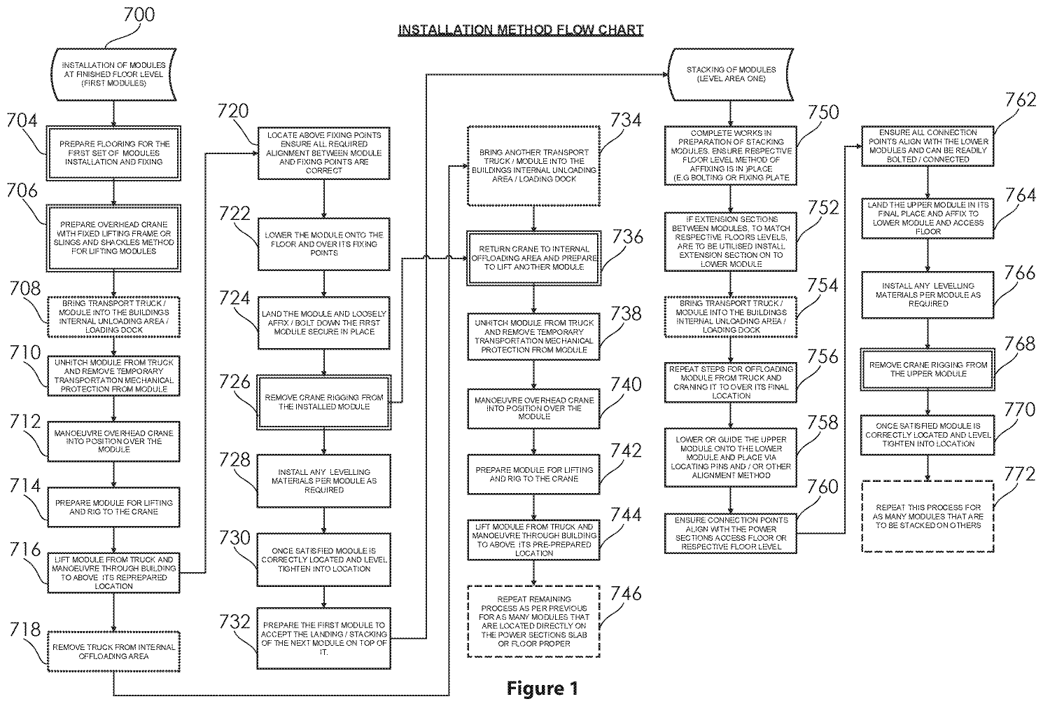

The embodiment of the power section 10 of FIGS. 1 to 7, includes a single base floor 23 and electrical equipment module stacks 71 and standby generator stacks 81 arranged on opposite sides of the building structure 20.

The embodiment of the power section 110 of FIGS. 8, 9 and 20, includes a single base floor 23 and electrical equipment module stacks 71 arranged on both sides of the building structure 20.

The embodiment of the power section 210 of FIGS. 10 to 12, includes a first base floor 23, a second base floor 223, a first lifting device 40 and a second lifting device 240. On both the first base floor 23 and the second base floor electrical equipment module stacks 71 and electrical standby generator stacks 81 arranged on opposite sides of the building structure 20.

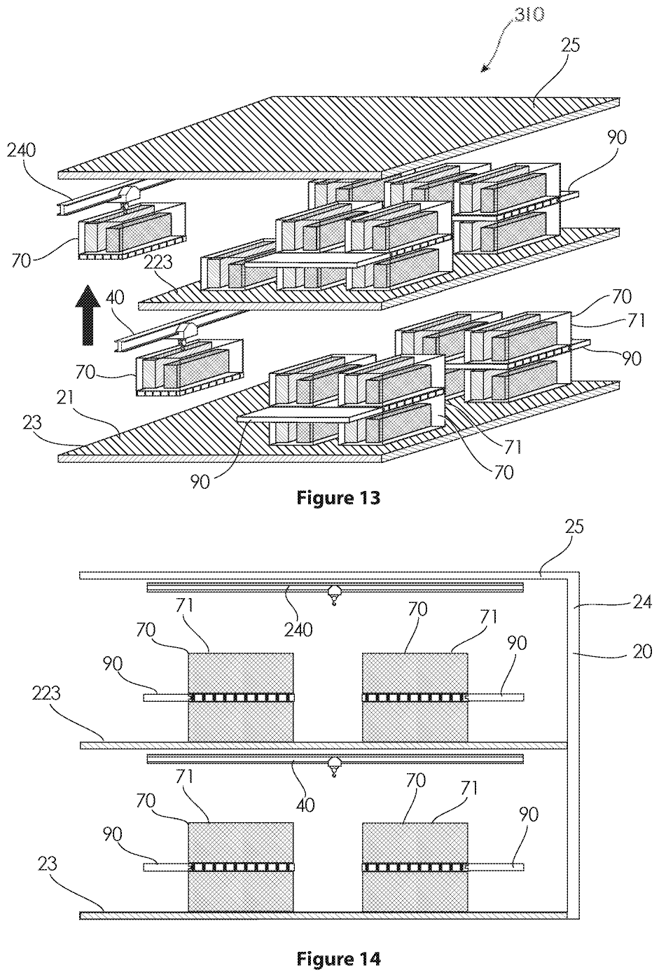

The embodiment of the power section 310 of FIGS. 13 and 14, includes a first base floor 23, a second base floor 223, a first lifting device 40 and a second lifting device 240. On both the first base floor 23 and the second base floor electrical equipment module stacks 71 are arranged on both sides of the building structure 20.

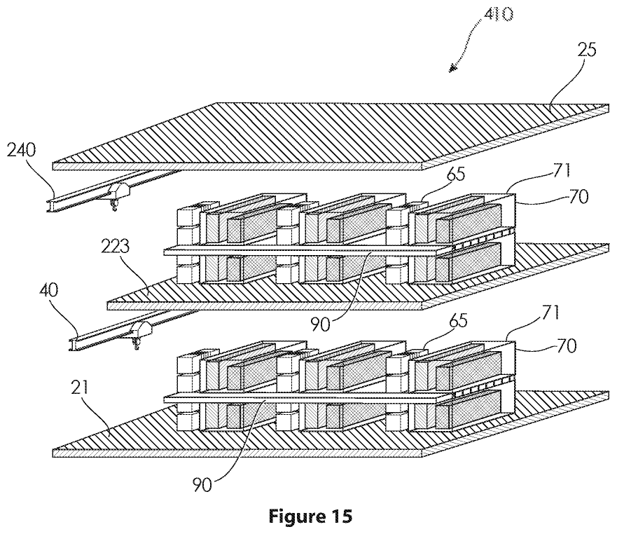

FIG. 15 illustrates an embodiment of the power section 410 including a first base floor 23, a second base floor 223, a first lifting device 40 and a second lifting device 240 and a single row of electrical equipment module stacks 71 on both the first base floor 23 and the second base floor 223. Transformer modules 65 are positioned adjacent to each of the electrical equipment modules 70. In an embodiment, the transformer modules are stackable and in another embodiment the transformer modules are not stackable and are placed upon floor members 90 adjacent to the electrical equipment modules 70.

FIGS. 16 and 17 illustrates an embodiment of the power section 510 including a first base floor 23, a second base floor 223, a first lifting device 40 and a second lifting device 240. On both the first base floor 23 and the second base floor electrical equipment module stacks 71 and electrical standby generator stacks 81 are arranged on opposite sides of the building structure 20. Transformer modules 65 are positioned adjacent to each of the electrical equipment modules 70. In an embodiment, the transformer modules are stackable and in another embodiment the transformer modules are not stackable and are placed upon floor members 90 adjacent to the electrical equipment modules 70.

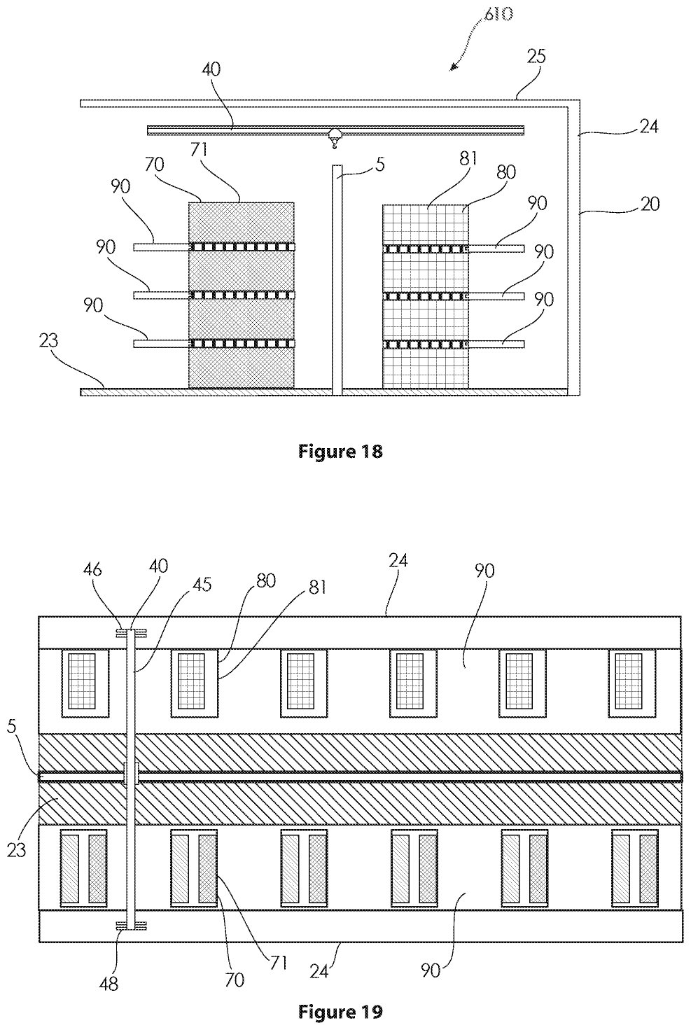

FIGS. 18 and 19 illustrates an embodiment of the power section 610 including a first base floor 23 and a lifting device 40. Electrical equipment module stacks 71 and electrical standby generator stacks 81 are arranged on opposite sides of the building structure 20. The building structure 20 contains a central dividing wall structure 5 extending in a longitudinal direction between the electrical equipment module stacks 71 and electrical standby generator stacks 81. The wall structure 84 may be formed by assembling together a plurality of precast panel members manoeuvred into position by the lifting device 40.

### Method

Embodiments of the invention include methods of assembling a power section of a data centre. Some steps of embodiments of the methods will be apparent from the above description of embodiments of the power sections 10, 110, 210, 310, 410, 510, 610 of FIGS. 3 to 19.

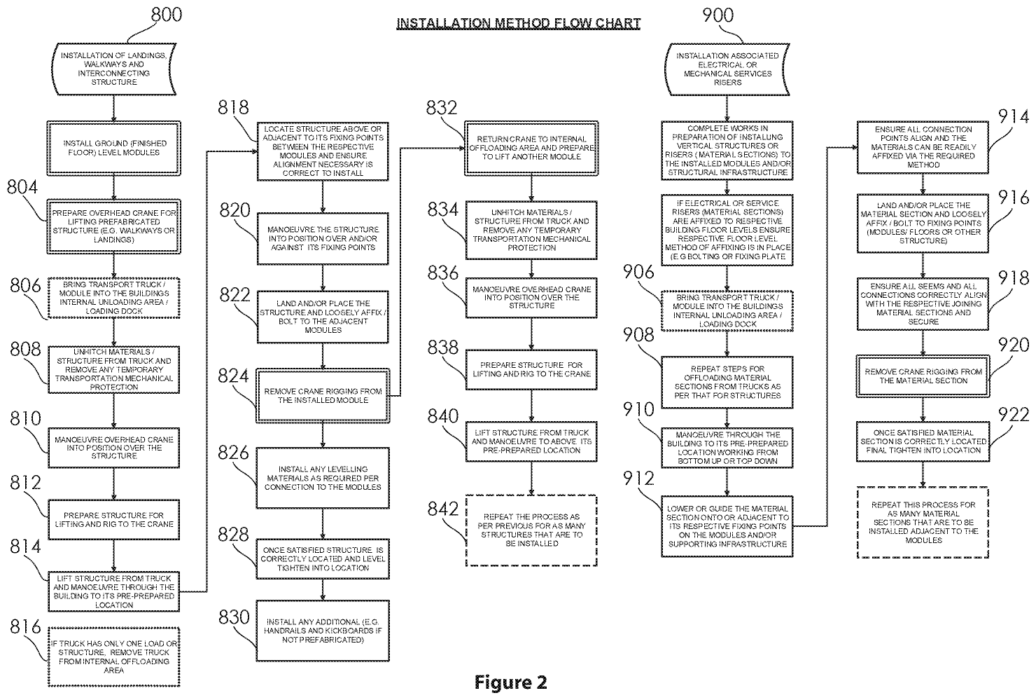

FIGS. 1 and 2 illustrate a method 700 of assembling a power section of a data centre according to an embodiment of the invention. FIG. 1 illustrates steps in a method of stacking power equipment modules 60, which may include electrical equipment modules 70 or standby generator modules 80 or both. FIG. 2 illustrates steps in a method of assembling floor members 90 and steps in a method of installing electrical or mechanical services within the building structure 20.

In embodiments of the method, the power equipment modules 60, which may include electrical equipment modules 70 or standby generator modules 80 or both, are prefabricated off-site and are skid mounted and loaded on a transport vehicle for delivery to the building structure 20 where they are manoeuvred to the loading area 21 and lifted by either one of the first and second lifting devices 40, 240. In further embodiments, the power section of a data centre, including the plurality of the power equipment modules 60, are assembled together off-site, preferably in a like building structure 20 in a trial assembly or fitting procedure. The power equipment modules 60 can be disassembled and loaded on a transport vehicle for delivery to the building structure 20 where they are manoeuvred to the loading area 21 and lifted by either one of the first and second lifting devices 40, 240.

The method broadly includes providing a supporting base 704, preferably involving preparing flooring. In a subsequent step, the method includes lifting a first power module above the supporting base and horizontally translating or manoeuvring the first power module to a desired location 716 and lowering the power module onto the supporting base 722. The method further includes lifting a second power module 744 above the supporting base, horizontally translating or manoeuvring and lowering the second power module onto the first power module 744.

In the embodiment of FIG. 1 a number of additional steps in the method are illustrated. After the step of providing or preparing the supporting base 704, the lifting device is preparing with slings and shackles or a spreader type device for lifting a power module 706. A transport vehicle including a power module loaded thereon is positioned in the loading area within the building structure 708 and is unhitched from the vehicle 710. A hoist of the lifting device is positioned above the module 712 and the hoist and module are coupled together 714. The power module is lifted by the hoist which is the translated horizontally to a desired location within the building structure 716. The vehicle may then be removed from the loading area 718.

The module is positioned above fixing points formed into the supporting base 720. As described above, these fixing points may be in the form of twist-lock devices formed into the floor surface. The hoist is operated to lower the module over the fixing points 722 and to land the module on the fixing points themselves 724. The hoist is disconnected form the module 726 and levelling materials may be provided to level the module on the fixing points 728. The module may then be finally locked into position 730 once levelled. The module may then be prepared for another module to be stacked thereon. This may include, for example, providing twistlock devices for corner castings of the module adapted to lock to the module below and to receive and lock together with another module placed thereon.

Another transport vehicle including another power module loaded thereon can be positioned in the loading area 734. The hoist of the lifting device is moved to the loading area 736 and the second module is unhitched from the vehicle 738. The hoist is positioned above the second module 740 and the hoist and module are coupled together 742. The second power module is lifted by the hoist which is the translated horizontally to a desired location within the building structure 744 which may be above another module to be stacked thereon or may be above fixing points formed into the supporting base 720. The hoist is operated to lower the second module onto another power module or onto the fixing points.

Where the second power module is to be stacked upon another power module, some preparation of the lower module may be required 750 such as providing fixing means, such as twistlock devices, on the lower module. In an embodiment, a spacer section may be positioned on the lower power module 752 that is approximately equivalent to the thickness of an adjacent floor panel. Another transport vehicle including another power module loaded thereon can be positioned in the loading area 754 and the previously mentioned steps of positioning the hoist above the vehicle, coupling the hoist to the power module and lifting and manoeuvring the module above another module 756.

The second module is lowered onto the module below 758. The location of the second module onto the first module may be assisted by locating points or some other alignment method. The module is positioned to ensure that the keyway in the base of the module for coupling with adjacent floor panels is properly aligned 760 and to ensure that the fixing points of the module above and the module below are also properly aligned 762. The upper module is lowered completely so that the entire weight thereof is supported on the module below and the modules are fixed together 764. The hoist is disconnected from the module and levelling materials may be provided to level the module on the fixing points 766.

The hoist of the lifting device is removed from the upper module 768. A final step of fixing together the upper and lower modules is competed 770. The abovementioned steps are repeated for successive power modules 772.

According to FIG. 2, there is shown an embodiment of a method of assembling floor member 800 within the building structure. The method includes a step of preparing the lifting device to lift prefabricated or precast floor panel members. As mentioned above, the floor members are preferably formed with anchors, such as mushroom or plate anchors and hoist of the lifting device is configured to employ lifting clutches for engaging the anchors. A transport vehicle including a floor members loaded thereon is positioned in the loading area within the building structure 806 and is unhitched from the vehicle 808. The hoist of the lifting device is positioned above the floor member 810 and the hoist and floor member are coupled together 812. The floor member is lifted by the hoist which is the translated horizontally to a desired location within the building structure 814. The vehicle may then be removed from the loading area 816.

The floor member is positioned above fixing points between adjacent power modules or between a power module and some other support structure to ensure correct alignment 818. The floor structure is then positioned over the fixing points 820 and lowered so as to land on the fixing points 822 to be loosely affixed thereto.

The hoist is disconnected from the floor member 824 and any levelling materials are provided to ensure that the floor member is level 826. The floor member may then be finally locked into position 828. Any handrails or other fixtures may then be connected to the installed floor panel 830.

Another transport vehicle including another floor member is positioned in the loading area and the hoist of the lifting device is moved to the loading area 832. The floor member is unhitched from the vehicle 834. The hoist is positioned above the floor member 836 and the hoist and floor member are coupled together 838. The floor member is lifted by the hoist which is then translated horizontally to a desired location within the building structure 840. The hoist is operated to lower the floor module which is then fixed in its final location in the same manner described above and the process is repeated until all of the floor members are installed 842.

According to FIG. 2, there is also shown an embodiment of a method of assembling electrical or mechanical services risers or other structures in the building structure 900. When works are completed for the installation of one or more power modules, floor member or other structures, a transport vehicle including electrical or mechanical services risers or other structures loaded thereon is positioned in the loading area within the building structure 906. The structure is unhitched from the vehicle, the hoist of the lifting device is positioned above the structure and the hoist and structure are coupled together 908. The structure is lifted off the vehicle by the hoist which is the translated horizontally to a desired location within the building structure 910.

The structure is lowered into position onto or near its fixing points on the power modules or some other supporting infrastructure 912. All connection points are aligned 914 and the structure is then lowered so as to land on the fixing points 916 to be loosely affixed thereto. All seams and all connections are properly aligned 918 and the hoist is disconnected and removed 920. The structure is finally checked for proper positioning and alignment and it finally fixed in position 922.

Embodiments of the method are also applicable for assembling a data section of a data centre. Such methods are substantially identical to the methods described above for assembling a power section of a data centre except that in place of power equipment modules 60 the method employ data equipment modules.

Although embodiments of the method 700 of assembling a power section of a data centre described above envisage assembling a complete data section in one continuous process, it is to be appreciated that assembly may occur in stages. For example, partial completion of a power section of a data centre may occur in a first stage and then final completion of the power section may occur in one or more subsequent stages occurring at different times. The data centre, including the power section 10 thereof, may be activated and brought online after completion of a first stage. The data centre, including the power section thereof, may be expanded after being brought online by completing additional stages.

Although the disclosure has been described with reference to specific examples, it will be appreciated by those skilled in the art that the disclosure may be embodied in many other forms, in keeping with the broad principles and the spirit of the disclosure described herein.

1. A data centre including:
a building structure comprising an internal space for containing equipment modules;
a lifting device adapted to lift, lower and move horizontally equipment modules within the internal space of the building structure.

2. The data centre of claim 1, wherein the lifting device includes a hoist for lifting and lowering an equipment module.

3. The data centre of claim 2, wherein the hoist is horizontally translatable to desired locations within the building structure.

4. The data centre of claim 1, wherein the lifting device includes a pair of spaced apart and longitudinally extending rails and a transverse beam extending between the rails, the beam being translatable in a longitudinal direction along the rail and the hoist being translatable transversely along the beam.

5. The data centre of claim 1, wherein the equipment modules are configured to be stacked one upon another.

6. The data centre of claim 1, wherein the building structure includes a base supporting the stacked equipment modules.

7. The data centre of claim 1, wherein the equipment modules can comprise electrical equipment modules comprising any one or more of medium voltage (MV) or low voltage (LV) switchboards, motor control centers (MCC's), uninterrupted power systems (UPS) and batteries, ring main units (RMU), transformers, bus duct equipment and controls.

8. (canceled)

9. The data centre of claim 1, wherein the equipment modules include structural support members that are adapted to support the weight of one or more equipment modules stacked thereon.

10.-12. (canceled)

13. The data centre of claim 1, wherein the building structure includes a second base and a second lifting device above or below the first base and the first lifting device.

14. The data centre of claim 13, wherein a second row of stacks of the electrical equipment modules and standby generator modules are provided on the second base.

15. The data centre of claim 13, wherein the upper one of the first and the second base includes an opening to allow the lifting device to lift and lower an electrical equipment module or a standby generator module therethrough.

16. The data centre of claim 1, wherein the building structure includes a loading area adapted for receiving an electrical equipment module or a standby generator module on a transport vehicle.

17. The data centre of claim 1, including floor members adapted to engage the equipment modules.

18. The data centre of claim 17, wherein the floor members are adapted for connection between successive horizontally adjacent equipment modules.

19. The data centre of claim 17, wherein the floor members are adapted to provide landings, walkways and function as interconnecting structures and to support electrical or mechanical services.

20. (canceled)

21. A method of assembling a data centre, the method including:
providing a supporting base;
lifting a first equipment module above the supporting base, horizontally translating the first equipment module to a desired location and lowering the equipment module onto the supporting base;
lifting a second equipment module above the supporting base, horizontally translating and lowering the second equipment module onto the first equipment module.

22. The method of claim 21, including positioning the equipment module beneath a lifting device comprising a hoist, lowering and coupling the hoist to the equipment module lifting the hoist and thereby lifting the equipment module coupled thereto.

23. (canceled)

24. The method of claim 21, including lifting, horizontally translating and lowering a floor member into a position for connection with at least one equipment module.

25. (canceled)

26. A prefabricated equipment module for a data centre of a data centre adapted to be stacked one upon another, the equipment module including:
a frame comprising a base for supporting electrical equipment and one or more support members upstanding from the base;
a coupling adapted to couple the bottom of the frame of one of the equipment modules to the top of the frame of a equipment module below.

27. The module of claim 26, wherein the coupling includes a mating element provided on the bottom of the frame of the upper equipment module and a complementary mating element provided on the top of the frame of the equipment module below, wherein the mating elements are configured to mate together to secure the equipment modules together.

28.-31. (canceled)
